(19) United States
(12) Patent Application Publication
(10) Pub. No.: US 2025/0149364 A1
(43) Pub. Date: May 8, 2025

(54) STAGE MOVING DEVICE

(71) Applicant: Samsung Display Co., LTD., Yongin-si (KR)

(72) Inventor: Jungwoong BYUN, Yongin-si (KR)

(21) Appl. No.: 18/781,319

(22) Filed: Jul. 23, 2024

(30) Foreign Application Priority Data
Nov. 8, 2023 (KR) 10-2023-0153220

(51) Int. Cl. H01L 21/677; H01F 7/20

(52) U.S. Cl. CPC H01L 21/67706; H01F 7/20

(57) ABSTRACT

A stage moving device includes a base part including an inner surface defining a guide groove, and a transporting part including a table disposed in the guide groove and an air spraying part disposed on a surface, of the table, facing the inner surface of the base part. The air spraying part includes an upper plate disposed on a lower surface of the table, a lower plate disposed below the upper plate, a motor part connected to the upper plate and the lower plate, and an air bag disposed between the upper plate and the lower plate and surrounding the motor part.

This application claims priority to Korean Patent Application No. 10-2023-0153220, filed on Nov. 8, 2023, and all the benefits accruing therefrom under 35 U.S.C. § 119, the content of which in its entirety is herein incorporated by reference.

### BACKGROUND

### 1. Field

The disclosure herein relates to a stage moving device.

### 2. Description of the Related Art

A display device, such as a television, a monitor, a smartphone, and a tablet computer that provide images to users, includes a display panel that displays images. Various display panels such as a liquid crystal display panel, an organic light emitting display panel, an electrowetting display panel, and an electrophoretic display panel are being developed as display panels.

As a resolution of a display panel increases, a clear image may be provided to a user. As a resolution of a display panel increases, the number of pixels in a unit area of the display panel may increase.

### SUMMARY

In a display panel with a high resolution, the number of pixels in a unit area becomes greater, a higher precision production technology is desired. To achieve a higher precision production, it is desired to convey a display panel with high precision.

Embodiment of the disclosure provide a stage moving device capable of compensating for errors in a moving direction of a table loaded with a display panel when the table is moved.

An embodiment of the invention provides a stage moving device including: a base part including an inner surface defining a guide groove; and a transporting part including a table disposed in the guide groove and an air spraying part disposed on a surface, of the table, facing the inner surface of the base part, where the air spraying part includes an upper plate disposed on a lower surface of the table, a lower plate disposed below the upper plate, a motor part connected to the upper plate and the lower plate, and an air bag disposed between the upper plate and the lower plate and surrounding the motor part.

In an embodiment of the invention, a stage moving device includes: a base part including an inner surface defining a guide groove; and a transporting part including a table disposed in the guide groove and an air spraying part disposed on a surface, of the table, facing the inner surface of the base part, where the air spraying part includes an upper plate disposed on a lower surface of the table, a lower plate disposed below the upper plate and provided with a spray port defined therein, and an air bag disposed between the upper plate and the lower plate, and an accommodation space defined by the air bag is filled with air.

### BRIEF DESCRIPTION OF THE DRAWINGS

The above and other features of the invention will become more apparent by describing in further detail embodiments thereof with reference to the accompanying drawings, in which:

FIG. 1 is a perspective view of a stage moving device according to an embodiment of the invention;

FIG. 2 is a side view of a stage moving device illustrated in FIG. 1;

FIG. 3 is a plan view of the stage moving device illustrated in FIG. 1;

FIG. 4 is a cross-sectional view taken along line I-I′ illustrated in FIG. 1;

FIGS. 5A to 5C are views for illustrating a movement of a transporting part illustrated in FIG. 1;

FIG. 6 is a view for illustrating compensation for errors in a moving path of a transporting part; and

FIGS. 7A to 7C are views for illustrating a stage moving device according to another embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or a layer is referred to as “being on an upper of” or “being on” another element or layer, it includes not only a case of being directly disposed on another element or layer, but also a case where intervening elements are disposed therebetween. On the contrary, when an element is referred to as “disposing directly on” or “disposing on top”, it means that there are no intervening layers or elements therebetween.

The spatially relative terms such as “below”, “beneath”, “lower”, “above”, “upper” and the like, may be used herein for ease of description to describe one element or feature's relationship to another element or feature as illustrated in the drawings. It will be understood that the spatially relative terms are intended to encompass different orientations of the device in use or operation in addition to the orientation depicted in the drawings.

It will be understood that, although the terms first, second, etc., may be used herein to describe various elements, components and/or sections, these elements, components and/or sections should not be limited by these terms. These terms are only used to distinguish one element, component, or section from another element, component or section. Thus, a first element, component, or section discussed below could be termed a second element, component, or section without departing from the teachings of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

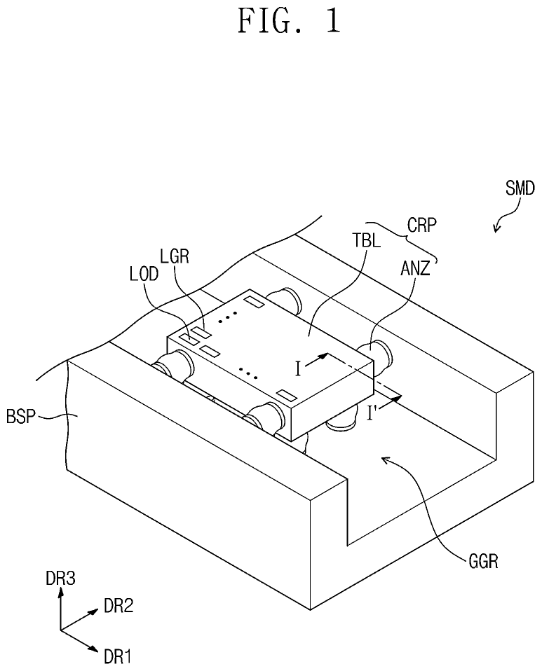

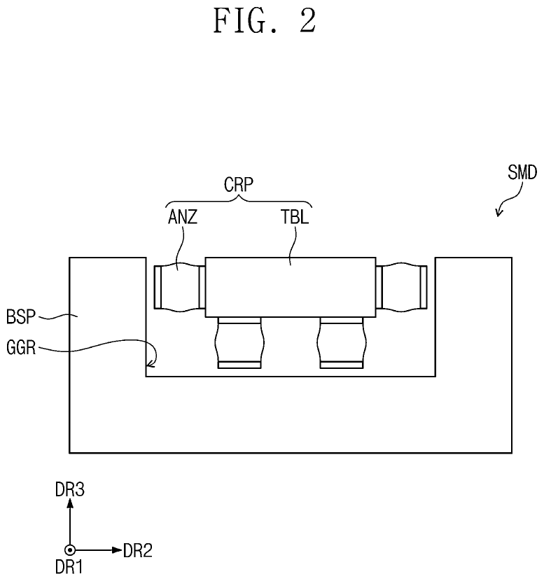

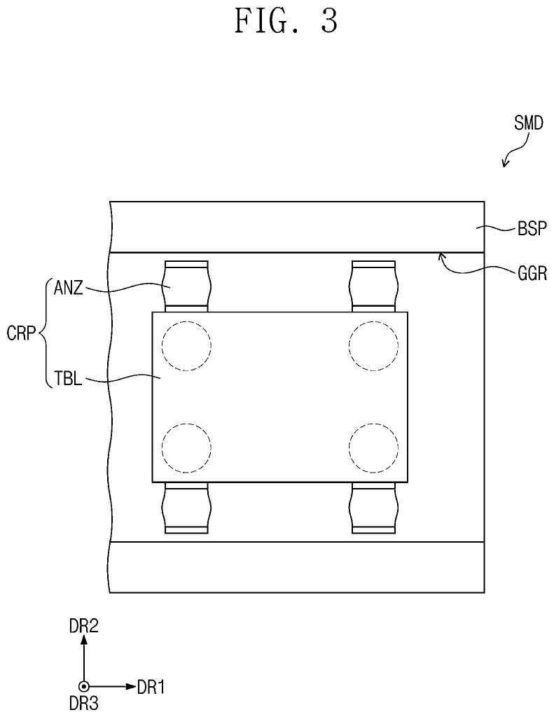

FIG. 1 is a perspective view of a stage moving device according to an embodiment of the invention. FIG. 2 is a side view of a stage moving device illustrated in FIG. 1. FIG. 3 is a plan view of the stage moving device illustrated in FIG. 1.

Referring to FIG. 1, an embodiment of a stage moving device SMD may include a base part BSP and a transporting part CRP. The transporting part CRP may include a table TBL and a plurality of air spraying parts ANZ. In an embodiment, for example, the table TBL may have a rectangular parallelepiped shape. An upper surface of the table TBL may have a rectangular shape which has long sides extending in a first direction DR1 and short sides extending in a second direction DR2 crossing the first direction DR1. However, an embodiment of the invention is not limited thereto, and the table TBL may have various shapes.

Hereinafter, a direction, which is substantially perpendicular to a plane defined by the first direction DR1 and the second direction DR2, is defined as a third direction DR3. In this specification, the wording “when viewed on a plane” or “in a plan view” may be defined as a state when viewed in the third direction DR3.

An upper surface of the table TBL may include a plurality of loading parts LGR. The loading parts LGR may be arranged in the first direction DR1 and the second direction DR2. In an embodiment, for example, as illustrated in FIG. 1, the loading parts LGR have a rectangular shape, but the shape of the loading parts LGR is not limited thereto.

In an embodiment, for example, the table TBL may include granite, but is not limited thereto. The table TBL may also include carbon, ceramic, an alloy, or the like.

A plurality of loads LOD may be loaded on the table TBL. The loads LOD may be respectively disposed on corresponding loading parts LGR among the loading parts LGR. In an embodiment, for example, the loads LOD may be display panels, or windows, but are not limited thereto.

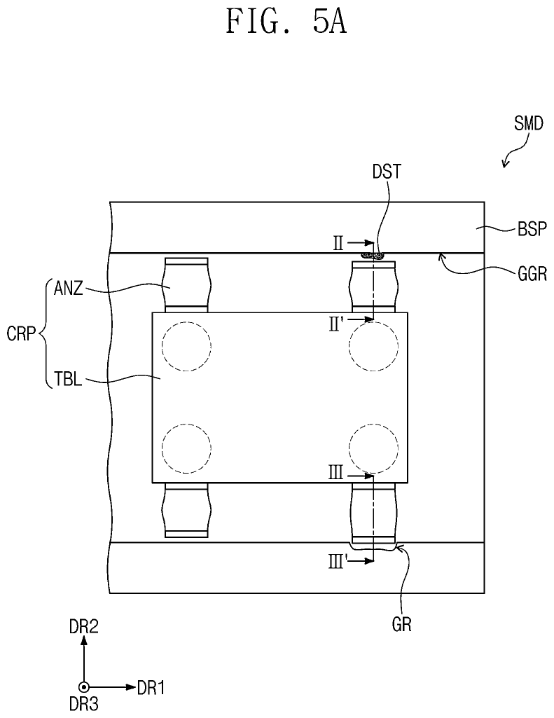

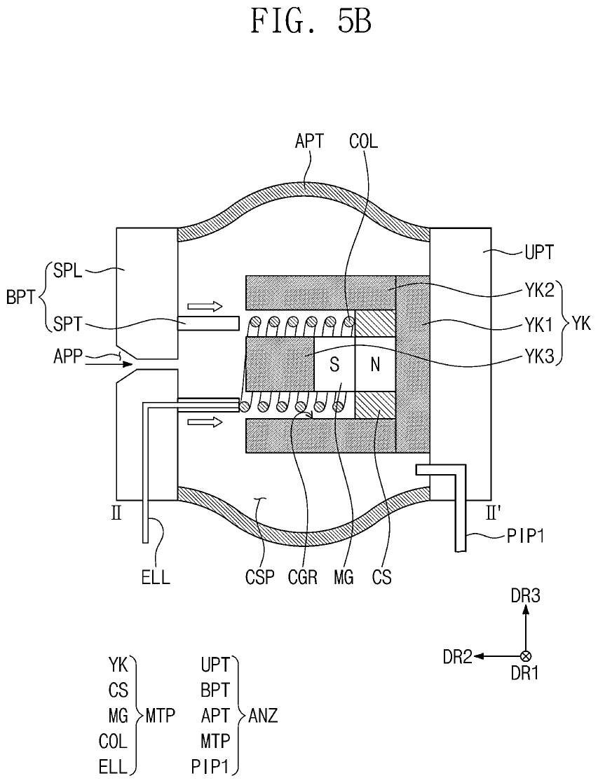

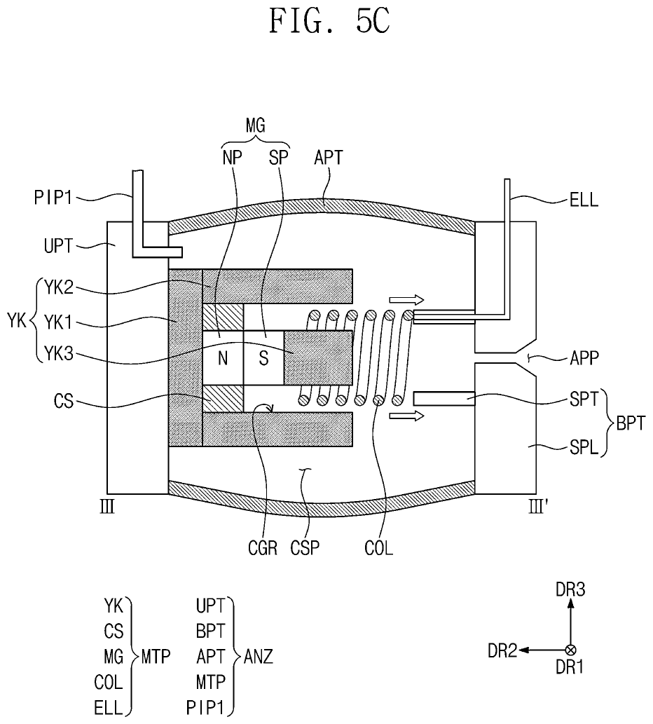

The loads LOD may be moved while being loaded on the table TBL. The movement of the table TBL will be described in detail with reference to FIGS. 5A to 5C.

Referring to FIGS. 1 to 3, the air spraying parts ANZ may be disposed on a lower surface of the table TBL and both opposing side surfaces of, the table TBL, which are opposed to each other in the second direction DR2. In an embodiment, for example, as illustrated in FIGS. 1 to 3, four air spraying parts ANZ are disposed on a lower surface of the table TBL, and two air spraying parts ANZ are disposed on both opposing side surfaces, of the table TBL, which are opposite to each other in the second direction DR2. However, the number of air spraying parts ANZ may not be limited thereto.

In an embodiment, for example, the air spraying parts ANZ may have a pillar shape. However, the air spraying parts ANZ are not limited thereto, and may have various shapes.

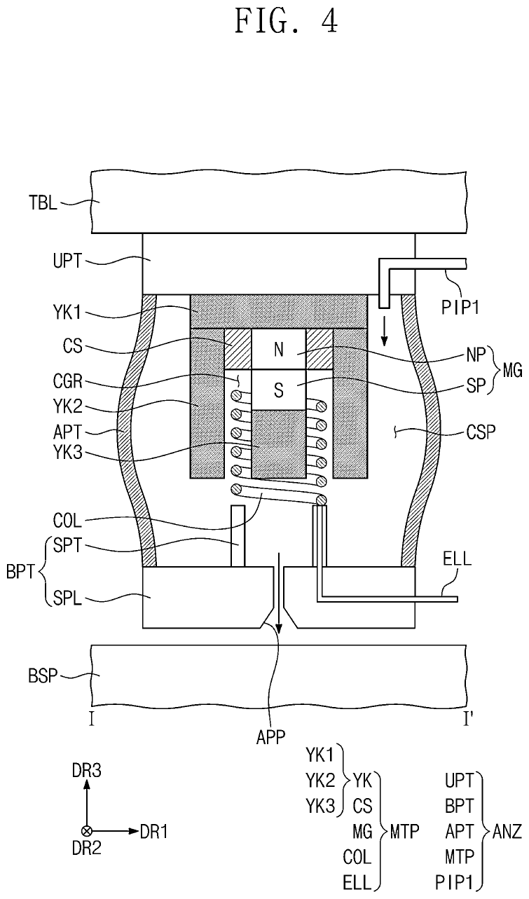

Air may be sprayed or jetted from surfaces, of the air spraying parts ANZ, in a direction facing the base part BSP to be described later. Due to air jetted by the air spraying parts ANZ, the table TBL may not contact the base part BSP. Spraying of the air from the air spraying parts ANZ will be described later in greater detail with reference to FIG. 4.

When viewed on a plane, the base part BSP may have a quadrilateral shape. When viewed in the third direction DR3, the base part BSP may have a partial shape of a rectangle which has long sides extending in a first direction DR1 and short sides extending in a second direction DR2. However, the shape of the base part BSP is not limited thereto, and may have various shapes.

A guide groove GGR may be defined in an upper surface of the base part BSP. The guide groove GGR may extend from an upper surface of the base part BSP toward a lower surface of the base part BSP. In an embodiment, for example, when viewed in the first direction DR1 as shown in FIG. 2, an inner surface of the base part BSP which defines the guide groove GGR may have a shape corresponding to a rectangle. The guide groove GGR may extend in the first direction DR1.

The transporting part CRP may be disposed inside the guide groove GGR. The transporting part CRP may move along the guide groove GGR in the first direction DR1. When the transporting part CRP moves, the loads LOD loaded on the transporting part CRP may be moved in the first direction DR1.

The table TBL and the air spraying parts ANZ may be disposed inside the guide groove GGR. Hereinafter, side surfaces, of the air spraying parts ANZ, facing inner surfaces of the base part BSP may be defined as one-side surfaces of the air spraying parts ANZ.

The one-side surfaces of the air spraying parts ANZ may spray air toward the inner surfaces of the base parts BSP. As the air spraying parts ANZ spray air, the table TBL may be spaced apart from the inner surfaces of the base part BSP. The transporting part CRP does not contact the inner surfaces of the base part BSP, and thus friction may not occur when the transporting part CRP moves along the guide groove GGR in the first direction DR1. Spraying of the air from the air spraying parts ANZ will hereinafter be described in detail with reference to FIG. 4.

FIG. 4 is a cross-sectional view taken along line I-I′ illustrated in FIG. 1.

Particularly, FIG. 4 is a cross-sectional view of one of the air spraying parts ANZ illustrated in FIG. 1.

For convenience of illustration and description, FIG. 4 illustrates only a part of a table TBL and a part of a base part BSP.

The table TBL and the base part BSP illustrated in FIG. 4 are the same as the table TBL and the base part BSP illustrated in FIG. 1, and thus any repetitive detailed description thereof will be omitted or simplified.

For example, one air spraying part ANZ among the plurality of air spraying parts ANZ illustrated in FIG. 1 will be described with reference to FIG. 4, but substantially, the description of the one air spraying part ANZ may be similarly applied to the other air spraying parts ANZ.

Referring to FIGS. 1 to 4, in an embodiment, the air spraying part ANZ may include an upper plate UPT, a lower plate BPT, an air bag APT, a first pipe PIP1, and a motor part MTP.

The upper plate UPT may be disposed on a lower surface of the table TBL. In an embodiment, for example, the upper plate UPT may have a disc-like shape, but is not limited thereto. The upper plate UPT may have various shapes. The lower plate BPT may be disposed below the upper plate UPT. The lower plate BPT may be disposed between the upper plate UPT and the base part BSP. In an embodiment, for example, the lower plate BPT may have a disc-like shape, but is not limited thereto. The lower plate BPT may have various shapes.

The lower plate BPT may include a support plate SPL and a support part SPT. The support plate SPL may be disposed below the upper plate UPT. The support plate SPL may be disposed between the upper plate UPT and the base part BSP. The support plate SPL may be spaced apart from the base part BSP by a predetermined distance in the third direction DR3. In an embodiment, for example, the support plate SPL may have a disc-like shape, but is not limited thereto. The support plate SPL may have various shapes.

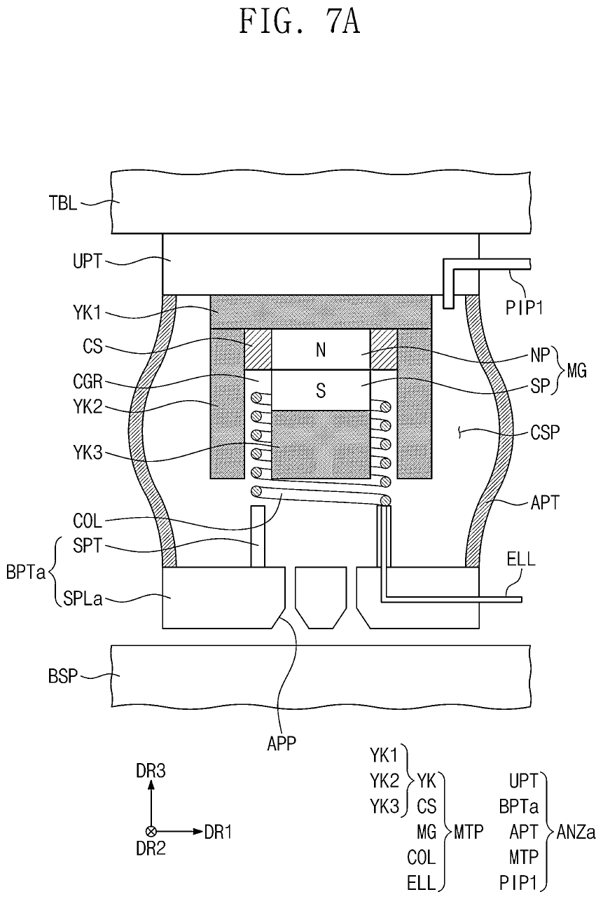

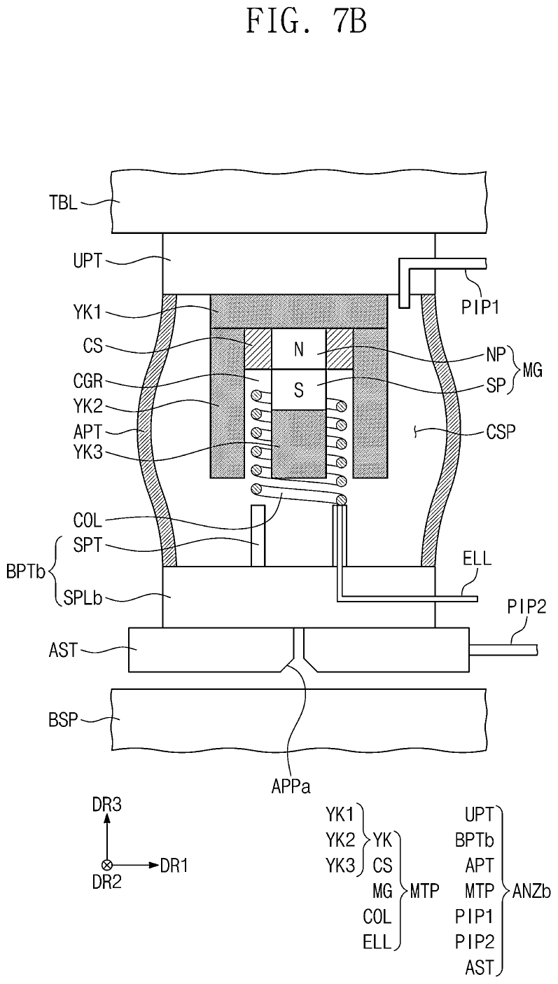

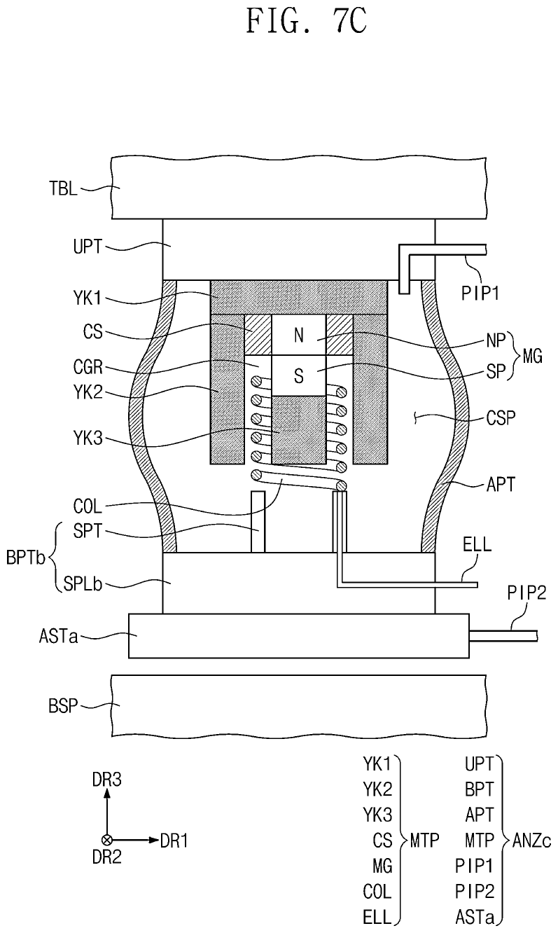

A spray port APP may be defined in the support plate SPL. The spray port APP may extend from an upper surface of the support plate SPL toward a lower surface of the support plate SPL in the third direction DR3. In an embodiment, for example, the spray port APP may have a shape of an orifice tube having a variable diameter. However, an embodiment of the invention is not limited thereto, and the spray port APP may be a porous vacuum chuck. A spray port APP according to another embodiment will be described later in detail with reference to FIGS. 7A to 7C.

In an embodiment, for example, as illustrated in FIG. 4, a single spray port APP is defined in one air spraying part ANZ, but the number of the spray ports APP is not limited thereto. The spray port APP may be defined in plurality. The detailed description thereof will be made with reference to FIG. 7A.

The support part SPT may be disposed on an upper surface of the support plate SPL. The support part SPT may extend from an upper surface of the support plate SPL toward the upper plate UPT. In an embodiment, the support part SPT and the support plate SPL may be integrally formed as a single unitary indivisible part.

Although not illustrated, the support part SPT may have a hollow cylindrical shape. Although not illustrated, when viewed on a plane, the support part SPT may surround the spray port APP.

The air bag APT may be disposed between the upper plate UPT and the lower plate BPT. The air bag APT may be connected to the upper plate UPT and the lower plate BPT. A space between the upper plate UPT and the lower plate BPT may be surrounded by the air bag APT. A space between the upper plate UPT and the lower plate BPT may be sealed by the air bag APT. The air bag APT may define an accommodation space CSP between the upper plate UPT and the lower plate BPT.

In an embodiment, for example, the accommodation space CSP and the spray port APP may be continuously defined or connected to each other. The spray port APP may be defined below the accommodation space CSP. The spray port APP may be more adjacent to the upper surface of the base part BSP than the accommodation space CSP. However, this is illustrated as an example, and the spray port APP and the accommodation space CSP may be separated from each other. The detailed description thereof will be made with reference to FIGS. 7A and 7B.

The first pipe PIP1 may pass through the upper plate UPT and extend to the accommodation space CSP. A part of the first pipe PIP1 may be disposed in the accommodation space CSP. The first pipe PIP1 may be connected to a pump (not illustrated) and inject air into the accommodation space CSP. When air is injected into the accommodation space CSP, the air bag APT may inflate.

As air is injected into the air bag APT, the air may apply pressure to the table TBL and the upper plate UPT in a direction opposite to a direction in which gravity acts on the table TBL and the upper plate UPT. Accordingly, the upper plate UPT and the table TBL may move in the third direction DR3 by the air injected into the air bag APT.

The air flowing into the accommodation space CSP may partially flow out to the outside via the spray port APP. The air pressure at an inlet of the spray port APP may be smaller than the air pressure at an outlet of the spray port APP. The inlet of the spray port APP may be defined as a portion of the spray port APP adjacent to an upper surface of the support plate SPL. The outlet of the spray port APP may be defined as a portion of the spray port APP adjacent to a lower surface of the support plate SPL. The air flowing out via the spray port APP may apply pressure to an inner surface of the base part BSP. Accordingly, a force may be applied to the air spraying part ANZ in a direction parallel to the third direction DR3. The air spraying part ANZ may be spaced apart from an inner surface of the base part BSP by the force.

The motor part MTP may be disposed between the upper plate UPT and the lower plate BPT. The motor part MTP may be disposed inside the accommodation space CSP. The motor part MTP may be surrounded by the air bag APT. The motor part MTP may be connected to the upper plate UPT and the lower plate BPT. The motor part MTP may be disposed on a lower surface of the upper plate UPT. The motor part MTP may be connected to the support part SPT of the lower plate BPT. The motor part MTP may control a distance between the upper plate UPT and the lower plate BPT. The distance between the upper plate UPT and the lower plate BPT of the motor part MTP will be described later in detail with reference to FIGS. 5A to 5C.

The motor part MTP may include a yoke YK, a damper CS, a magnet MG, a coil COL, and an electrical wire ELL. The yoke YK may be disposed between the upper plate UPT and the lower plate BPT. The yoke YK may be disposed on a lower surface of the upper plate UPT.

In an embodiment, for example, the yoke YK may include Fe. However, an embodiment of the invention is not limited thereto, and the yoke YK may include another material. The yoke YK may serve as a path through which magnetic field lines of the magnet MG to be described later pass.

The yoke YK may include a first yoke YK1, a second yoke YK2, and a third yoke YK3. The first yoke YK1 may be disposed on a lower surface of the upper plate UPT. Although not illustrated, for example, the first yoke YK1 may have a disc-like shape. However, an embodiment of the invention is not limited thereto, and the first yoke YK1 may have another shape.

The second yoke YK2 may be disposed between the first yoke YK1 and the lower plate BPT. The second yoke YK2 may be disposed on a lower surface of the first yoke YK1. Although not illustrated, the second yoke YK2 may have a cylindrical shape.

An accommodation groove CGR may be defined by the second yoke YK2. The accommodation groove CGR may be defined inside the second yoke YK2. Although not illustrated, the accommodation groove CGR may have a shape corresponding to a cylinder. However, the shape of the accommodation groove CGR is not limited thereto.

The magnet MG may be disposed in the accommodation groove CGR. The magnet MG may be disposed on a lower surface of the first yoke YK1. The magnet MG may include a first pole NP and a second pole SP. The first pole NP may be the north (N) pole. The second pole SP may be the south(S) pole. In an embodiment, for example, the second pole SP may be disposed below the first pole NP. The first pole NP may be disposed on a lower surface of the first yoke YK1, and the second pole SP may face the lower plate BPT. However, this is illustrated as an example, and the first pole NP may be disposed below the second pole SP.

The damper CS may be disposed in the accommodation groove CGR. The damper CS may be disposed between the coil COL to be described later and the first yoke YK1 on the basis of the third direction DR3. Although not illustrated, the damper CS may surround the periphery of the magnet MG. The damper CS may support the coil COL when an electric current is not applied to the coil COL to be described later.

The third yoke YK3 may be disposed in the accommodation groove CGR. The third yoke YK3 may be disposed between the magnet MG and the lower plate BPT. The third yoke YK3 may be disposed on a lower surface of the magnet MG.

The coil COL may be connected to the support part SPT of the lower plate BPT. The coil COL may be disposed on an upper surface of the support part SPT. The coil COL may have a solenoid-like shape. The magnet MG and the third yoke YK3 may be surrounded by the coil COL. Although not illustrated, for example, the coil COL may have a hollow cylindrical shape, but have a hollow square pillar shape without being limited thereto.

The electrical wire ELL may pass through the lower plate BPT to be connected to the coil COL. Although not illustrated, the electrical wire ELL may apply an electric current from an external power source to the coil COL.

When an electric current flows in the coil COL through the electrical wire ELL, the Lorentz's force may act on the coil COL. The Lorentz' force may be generated by a magnetic field of the magnet MG and an electric current flowing in the coil COL. The Lorentz's force may be defined as a force exerted on a conductive wire due to a force acting on moving electric charges when an electric current flows in the conductive wire which is present in a magnetic field.

A direction of the Lorentz's force may follow the Fleming's left hand rule. The Fleming's left hand rule may be defined as a rule to determine the direction of a force which acts on a conducive wire when a direction of the magnetic field and a direction of the flowing electric current are given. The direction of the Lorentz's force may vary based on the direction of the magnetic field of the magnet MG and the direction of the electric current flowing in the coil COL. Accordingly, a moving direction of the coil COL may be changed, and thus an area of the magnet MG surrounded by the coil COL may increase or decrease. A gap between the lower plate BPT connected to the coil COL and the upper plate UPT connected to the magnet MG is variable.

A gravity, acting on the table TBL and the upper plate UPT, may be offset by the pressure of air flowing into the accommodation space CSP. Accordingly, due to the Lorentz's force being relatively smaller than gravity, the gap between a lower surface of the upper plate UPT and an inner surface of the base part BSP may be easily or effectively controlled. That is, due to the Lorentz's force, the gap between a lower surface of the upper plate UPT and an upper surface of the lower plate BPT may be finely controlled. Since the gap between a lower surface of the upper plate UPT and an upper surface of the lower plate BPT may be finely controlled, it is possible to easily compensate for errors in a moving path of the transporting part CRP (see FIG. 1) when the transporting part CRP (see FIG. 1) moves along the guide groove GGR. The compensation for errors by the air spraying part ANZ will be described in detail with reference to FIGS. 5A to 5C.

FIGS. 2 to 4 illustrate one air spraying part ANZ disposed on a lower surface of the table TBL, but the above description may also be similarly applied to other air spraying parts ANZ disposed on a lower surface of the table TBL and the air spraying parts ANZ disposed on both side surfaces of, the table TBL, which are opposed to each other in the first direction DR1.

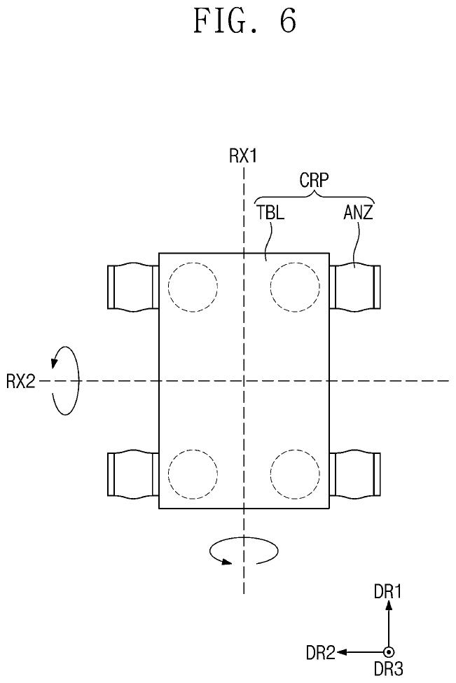

FIGS. 5A to 5C are views for illustrating a movement of a transporting part illustrated in FIG. 1. FIG. 6 is a view for illustrating compensation for errors in a moving path of a transporting part.

Particularly, FIG. 5A is a plan view, FIG. 5B is a cross-sectional view taken long line II-II′, and FIG. 5C is a cross-sectional view taken along line III-III′.

For convenience of illustration and description, FIG. 5A illustrates only a part of a base part BSP.

For convenience of illustration and description, in FIG. 5A, the loads LOD of FIG. 1, and the first pipe PIP1 and the electrical wire ELL of FIG. 4 are omitted.

A table TBL, an air spraying part ANZ, and a guide groove GGR of a base part BSP, which are illustrated in FIGS. 5A to 5C are the same as the table TBL, the air spraying part ANZ, and the base part BSP, which are illustrated in FIGS. 1 to 4, and thus any repetitive detailed description thereof will be omitted or simplified.

Referring to FIGS. 1 and 5A, although not illustrated, the stage moving device SMD may further include a sensor. The sensor may measure a distance between a lower surface of the table TBL and an inner surface of the base part BSP, and distances between side surfaces of the table TBL and an inner surface of the base part BSP. Additionally, the sensor may measure a moving direction of the table TBL.

Referring to FIGS. 5A and 5B, the transporting part CRP may move according to set path information. The set information may include information about a moving direction. In an embodiment, for example, the transporting part CRP moves in the first direction DR1, but a moving direction of the transporting part CRP is not limited thereto.

When the transporting part CRP moves, air may flow into the accommodation space CSP via the first pipe PIP1 (see FIG. 4). The air flowing into the accommodation space CSP may partially flow out to the spray port APP (see FIG. 4).

Due to air sprayed from the spray port APP illustrated in FIG. 4, the transporting part CRP may not contact an inner surface of the base part BSP which defines the guide groove GGR. Therefore, a frictional force may not act between the transporting part CRP and the inner surface of the base part BSP.

The set information may further include information for errors in a moving direction. For example, a foreign substance DST may be accumulated on the inner surface of the base part BSP. The foreign substance DST may protrude from the inner surface of the base part BSP. When the transporting part CRP passes the foreign substance DST, the moving path of the transporting part CRP may be changed due to the foreign substance DST. Therefore, errors may occur in a moving path of the table TBL. The set information may include information for errors caused by the foreign substance DST.

The set information may include compensation information for errors. The transporting part CRP according to an embodiment of the invention may compensate for errors in the moving path according to the set information. In an embodiment, an electric current may be applied to the coil COL via the electrical wire ELL to compensate for the errors in the moving path using the set information when the transporting part CRP passes the foreign substance DST.

When an electric current flows in the coil COL, the Lorentz's force may be generated in the coil COL by the electric current flowing in the coil COL and a magnetic field of the magnet MG. The Lorentz's force may act on the coil COL in a direction parallel to a direction opposed to the second direction DR2. The Lorentz's force may act on the coil COL in a direction headed toward the accommodation groove CGR. Accordingly, the coil COL may move toward the accommodation groove CGR. An area of the magnet MG surrounded by the coil COL may increase.

When the coil COL moves, the lower plate BPT connected to the coil COL may move in a direction opposed to the second direction DR2. Accordingly, since a distance between an upper surface of the lower plate BPT and a lower surface of the upper plate UPT decreases, it is possible for the motor part MTP to compensate for errors caused by the foreign substance DST. Therefore, the foreign substance DST may not change the moving path of the table TBL.

Also, as the accommodation space CSP is filled with air, the air in the accommodation space CSP may apply pressure to the upper plate UPT. The upper plate UPT may transmit a force caused by the pressure to the table TBL. Accordingly, a force caused by air pressure and an external force acting on the table TBL may be mutually offset. As the external force acting on the table TBL is offset, the motor part MTP may precisely compensate for errors in the moving path of the table TBL by using the Lorentz's force. Therefore, the motor part MTP may precisely and easily compensate for errors in the moving path of the transporting part CRP.

Referring to FIGS. 5A and 5C, a groove RG may be defined in the inner surface of the base part BSP. The groove RG may be more recessed than the inner surface of the base part BSP. Accordingly, when the transporting part CRP passes the groove GR, the moving path of the transporting part CRP is changed, and thus errors in the moving path of the transporting part CRP may occur.

In an embodiment, an electric current may be applied to the coil COL to compensate for errors using the set information. A direction in which the applied electric current flows in FIG. 5C may be opposed to a direction in which the applied electric current flows in FIG. 5B.

The air spraying part ANZ may compensate for errors according to the set information. In an embodiment, when an electric current is applied to the coil COL, the Lorentz's force may be generated by a magnetic field of the magnet MG and the electric current of the coil COL. The Lorentz's force may act on the coil COL in a direction opposed to the second direction DR2. Accordingly, the coil COL may move in a direction opposed to the second direction DR2. The coil COL may move to be exposed to the outside from the accommodation groove CGR. An area of the magnet MG surrounded by the coil COL may decrease.

When the coil COL moves in a direction DR2 opposed to the second direction DR2, the lower plate BPT connected to the coil COL may move in the direction DR2 opposed to the second direction DR2. As the lower plate BPT moves in the direction DR2 opposed to the second direction DR2, a distance between a lower surface of the upper plate UPT and an upper surface of the lower plate BPT may increase. The motor part MTP may compensate for errors caused by the groove GR.

In this case, due to air into accommodation space CSP, a force caused by air pressure and external forces acting on the table TBL may be mutually offset. Accordingly, the motor part MTP may precisely compensate for errors in the moving path of the table TBL. Therefore, the transporting part CRP may precisely and easily move.

FIGS. 5A to 5C illustrate the air spraying parts ANZ disposed on side surfaces, of the table TBL, which are opposed to each other in the second direction DR2, but an embodiment of the invention is not limited thereto. The above description may also be similarly applied to the air spraying parts ANZ disposed on a lower surface of the table TBL.

Referring to FIGS. 5B and 5C, the compensation for the errors occurring on a plane defined by the first direction DR1 and the second direction DR2 is described, but an embodiment of the invention is not limited thereto.

Errors in the moving path of the transporting part CRP may occur in the third direction DR3. For example, when a foreign substance or a groove is present on the inner surface of the base part BSP which defines a guide groove GGR, errors in the moving path may occur in the third direction DR3. In this case, the air spraying parts ANZ disposed on a lower surface of the table TBL may be applied with an electric current according to the set information and compensate for the errors in the moving path in the third direction DR3.

Referring to FIG. 6, the errors in the moving path of the transporting part CRP may include a case of rotation at a predetermined angle with respect to a first rotation axis RX1 parallel to the first direction DR1. For example, when viewed on a plane, the height of a left side of the table TBL may be smaller than the height of a right side of the table TBL with respect to the first rotation axis RX1.

In this case, the air spraying parts ANZ disposed on a lower surface of the table TBL may receive an electric current according to the set information. The coils COL which receives the electric current may move. In an embodiment, for example, with respect to the first rotation axis RX1, the coils COL of the air spraying parts ANZ disposed on a left lower side of the table TBL may move in a direction headed toward the outside of the accommodation groove CGR. The coils COL of the air spraying parts ANZ disposed on a right lower surface of the table TBL may move in a direction headed toward the inside of the accommodation groove CGR. Accordingly, errors in the moving path of the table TBL may be compensated.

The errors in the moving path of the transporting part CRP may include an error of rotation at a predetermined angle with respect to a second rotation axis RX2 parallel to the second direction DR2. For example, when viewed on a plane, the height of an upper part of the table TBL may be smaller than the height of a lower part of the table TBL with respect to the second rotation axis RX2.

In this case, the air spraying parts ANZ disposed on a lower surface of the table TBL may receive an electric current according to the set information. The coils COL which receives the electric current may move. For example, with respect to the second rotation axis RX2, the coils COL of the air spraying parts ANZ disposed on an upper part of the table TBL may move in a direction headed toward the outside of the accommodation groove CGR. The coils COL of the air spraying parts ANZ disposed on a lower part of the table TBL may move in a direction headed toward the inside of the accommodation groove CGR. Accordingly, errors in the moving path of the table TLB may be compensated.

Also, as an air bag APT of the air spraying parts ANZ is filled with air, external forces including gravity acting on the table TBL may be mutually offset. Accordingly, compensation for the errors in the moving path of the table TBL of the motor parts MTP may be precisely performed. Therefore, the transporting part CRP may precisely and easily move.

FIGS. 7A to 7C are views for illustrating a stage moving device according to another embodiment of the invention.

Referring to FIGS. 7A to 7C, the description of the stage moving device will be focused on air spraying parts ANZa, ANZb, and ANZc.

Particularly, FIGS. 7A to 7C are cross-sectional views taken along line I-I′ illustrated in FIG. 1.

For convenience of illustration and description, FIGS. 7A to 7C illustrate only a part of the table TBL and a part of the base part BSP, which are illustrated in FIG. 1.

A table TBL, a base part BSP, a motor part MTP, and an air bag APT illustrated in FIGS. 7A to 7C are the same as the table TBL, the base part BSP, and the motor part MTP illustrated in FIG. 4, and thus any repetitive detailed description thereof will be omitted or simplified.

Referring to FIG. 7A, in an embodiment, a plurality of spray ports APP may be defined in a support plate SPLa of a lower plate BPTa. The spray ports APP of FIG. 7A may be substantially the same as the spray port APP of FIG. 4. When viewed in the second direction DR2, the spray ports APP may be aligned in the first direction DR1.

Air flowing into an accommodation space CSP via a first pipe PIP1 may flow out to the outside via the spray ports APP. In an embodiment, for example, the spray ports APP may have an orifice tube-like shape. The air pressure at inlets of the spray ports APP may be smaller than the air pressure at outlets of the spray ports APP. The air flowing out via the spray ports APP may apply pressure to the base part BSP. Accordingly, the air spraying part ANZa may be spaced apart from the inner surface of the base part BSP.

Referring to FIG. 7B, in an embodiment, the air spraying part ANZb may further include a second pipe PIP2 and a jetting part AST. The jetting part AST may be disposed below a lower plate BPTb. The jetting part AST may be disposed on a lower surface of the lower plate BPTb. A spray port APPa may be defined in the jetting part AST. The spray port APPa may not be defined in a support plate SPLb. In an embodiment, for example, the spray port APPa may have an orifice tube-like shape.

The spray port APPa and the accommodation space CSP may be separated from each other. The spray port APPa and the accommodation space CSP may be blocked from each other by the lower plate BPTb. Accordingly, air flowing into the accommodation space CSP from the first pipe PIP1 may not flow out to the spray port APPa.

The second pipe PIP2 may be connected to the jetting part AST. The second pipe PIP2 may allow air to flow into the jetting part AST from a pump (not illustrated). The air flowing into the jetting part AST may flow out to the outside via the spray port APPa. The air flowing out to the outside may apply pressure to the inner surface of the base part BSP, and the air spraying part ANZb may be spaced apart from the base part BSP.

Referring to FIG. 7C, in an embodiment, the spray port ASTa may have a porous chuck type. The porous chuck type may be defined as a type in which air flows out via fine openings (not illustrated). When air flows into the spray port ASTa connected to the second pipe PIP2, the air may flow out via the fine openings (not illustrated). The air which flows out may apply pressure to the inner surface of the base part BSP. Accordingly, the air spraying part ANZc may be spaced apart from the base part BSP.

According to an embodiment of the invention, air spraying parts disposed on a lower surface and a side surface of a table loaded with a display panel may include an upper plate connected to the table, a lower plate disposed below the upper plate, a motor part disposed between the upper plate and the lower plate, and an air bag surrounding the motor part. The air bag is disposed between the upper plate and the lower plate, and when the air bag is filled with air, air pressure and an external force applied to the table may be mutually offset. Therefore, the motor part may easily compensate for errors occurring in a plurality of directions in a moving path of the table.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A stage moving device comprising:
a base part including an inner surface defining a guide groove; and
a transporting part including a table disposed in the guide groove and an air spraying part disposed on a surface, of the table, facing the inner surface of the base part,
wherein the air spraying part includes
an upper plate disposed on a lower surface of the table,
a lower plate disposed below the upper plate,
a motor part connected to the upper plate and the lower plate, and
an air bag disposed between the upper plate and the lower plate and surrounding the motor part.

2. The stage moving device of claim 1, wherein the motor part comprises:
a first yoke disposed on a lower surface of the upper plate;
a second yoke disposed on a lower surface of the first yoke and defining an accommodation groove;
a magnet disposed in the accommodation groove;
a coil connected to the lower plate and surrounding the magnet; and
an electrical wire which supplies an electric current to the coil.

3. The stage moving device of claim 2, wherein when the electric current flows in the coil through the electrical wire, an area of the magnet surrounded by the coil varies based on a direction in which the electric current flows.

4. The stage moving device of claim 3, wherein a gap between the upper plate and the lower plate varies based on a direction in which an electric current flows in the coil.

5. The stage moving device of claim 2, wherein the motor part further comprises a third yoke disposed on a lower surface, of the magnet, facing the lower plate, and
the third yoke is disposed in the accommodation groove.

6. The stage moving device of claim 2, wherein the motor part further comprises a damper disposed between the coil and the first yoke, and
the damper surrounds the magnet disposed in the accommodation groove.

7. The stage moving device of claim 2, wherein the lower plate comprises:
a support part connected to the coil; and
a support plate disposed under the support part and provided with a spray port defined therein.

8. The stage moving device of claim 1, wherein the air spraying part further comprises a first pipe through which air is injected into an accommodation space defined by the air bag, and
the motor part is disposed in the accommodation space.

9. The stage moving device of claim 8, wherein
a spray port is defined in the lower plate, and
the spray port and the accommodation space are connected to each other.

10. The stage moving device of claim 9, wherein
air injected into the accommodation space flows out to an outside via the spray port, and
the spray port has an orifice tube-like shape.

11. The stage moving device of claim 10, wherein the spray port is defined in plurality.

12. The stage moving device of claim 8, wherein the air spraying part further comprises:
a jetting part disposed on a lower surface of the lower plate and provided with a spray port defined therein; and
a second pipe through which air is injected into the jetting part, and
wherein the spray port and the accommodation space are blocked from each other by the lower plate, and
air injected into the jetting part flows out to an outside via the spray port.

13. The stage moving device of claim 12, wherein the spray port has an orifice tube-like shape.

14. The stage moving device of claim 12, wherein the spraying part is a porous vacuum chuck type.

15. A stage moving device comprising:
a base part including an inner surface defining a guide groove; and
a transporting part including a table disposed in the guide groove and an air spraying part disposed on a surface, of the table, facing the inner surface of the base part,
wherein the air spraying part includes:
an upper plate disposed on a lower surface of the table;
a lower plate disposed below the upper plate and provided with a spray port defined therein; and
an air bag disposed between the upper plate and the lower plate, and
wherein an accommodation space defined by the air bag is filled with air.

16. The stage moving device of claim 15, wherein the air spraying part further comprises a motor part disposed in the accommodation space.

17. The stage moving device of claim 16, wherein the motor part comprises:
a first yoke disposed on a lower surface of the upper plate;
a second yoke disposed on a lower surface of the first yoke and defining an accommodation groove;
a magnet disposed in the accommodation groove;
a third yoke disposed on a lower surface, of the magnet, facing the lower plate;
a coil connected to the lower plate and surrounding the magnet; and
an electrical wire connected to the coil to supply an electric current.

18. The stage moving device of claim 17, wherein an area of the magnet surrounded by the coil varies based on a direction in which the electric current flows in the coil.

19. The stage moving device of claim 18, wherein a gap between the upper plate and the lower plate varies based on a direction in which an electric current flows in the coil.

20. The stage moving device of claim 15, wherein
the air spraying part further comprises a first pipe through which air is injected into the accommodation space,
the accommodation space and the spray port are connected to each other, and
the air injected into the accommodation space flows out to an outside via the spray port.
